(19) United States
(12) Patent Application Publication
(10) Pub. No.: US 2007/0204957 A1
(43) Pub. Date: Sep. 6, 2007

(54) Plasma processing of large workpieces

(76) Inventors: Steven D. Braymen, Ames, IA (US); Frank R. Jeffrey, Ames, IA (US); Curtis F. Sell, Elk Grove, IL (US)

Correspondence Address: COOLEY GODWARD KRONISH LLP;ATTN: PATENT GROUP, Suite 500, 1200 - 19th Street, NW, WASHINGTON, DC, 20036-2402, US

(21) Appl. No.: 11/364,550

(22) Filed: Mar. 1, 2006

(51) Int. Cl. C23F 1/00; H01L 21/306

(52) U.S. Cl. 156/345.31; 156/345.51; 156/345.48

(57) ABSTRACT

An apparatus includes a chamber having a process zone. The chamber is configured to contain a substrate, an etching substance, and an antenna. The antenna is configured to activate the etching substance. The substrate includes a material formulated to be etched by the etching substance when the etching substance is activated. The apparatus also includes a transfer mechanism. The transfer mechanism is configured to move the substrate from a first position to a second position. A first portion of the substrate is disposed within the process zone and a second portion of the substrate is disposed outside the process zone when the substrate is in its first position. The first portion of the substrate is disposed outside the process zone and the second portion of the substrate is disposed inside the process zone when the substrate is in its second position. The size and geometry of the antenna can be chosen to allow the etching of a grounded substrate.

### BACKGROUND

This invention relates generally to an etching apparatus and more specifically to a plasma or reactive ion etching apparatus that allows a substrate, such as a semiconductor substrate, to be etched as the substrate moves through or within a process chamber.

Known techniques for processing a series of semiconductor substrates are batch processing techniques. Using a batch processing technique, the processed semiconductor substrates must be replaced with unprocessed semiconductor substrates before the etching cycle can be restarted. Accordingly, the known batch processing techniques are labor and time intensive.

Known batch processing techniques are also limited in the size of the semiconductor substrate that can be processed or etched. Specifically, known batch processing techniques cannot be used to etch semiconductor substrates that are larger than the mechanism used to activate the etching substance.

Thus, there is a need for an apparatus configured to etch a series of substrates and/or a large substrate in an efficient manner. Additionally, there is a need for an apparatus that is configured to etch a large substrate using continuous processing techniques

### SUMMARY

An apparatus includes a chamber having a process zone. The chamber is configured to contain a substrate, an etching substance, and an antenna. The antenna is configured to activate the etching substance. The substrate includes a material formulated to be etched by the etching substance when the etching substance is activated. The apparatus also includes a transfer mechanism. The transfer mechanism is configured to move the substrate from a first position to a second position. A first portion of the substrate is disposed within the process zone and a second portion of the substrate is disposed outside the process zone when the substrate is in its first position. The first portion of the substrate is disposed outside the process zone and the second portion of the substrate is disposed inside the process zone when the substrate is in its second position.

### BRIEF DESCRIPTION OF THE DRAWINGS

The invention is described with reference to the accompanying drawings. In the drawings, like reference numbers indicate identical or functionally similar elements.

FIG. 1 is a schematic view of an apparatus according to an embodiment of the invention.

FIG. 2 is a perspective view of portions of an apparatus according to an embodiment of the invention.

FIG. 3 is a partial cut away view of the apparatus of FIG. 2.

FIG. 4 is a cross-sectional view of the antenna of the apparatus of FIG. 2 taken along the line A-A in FIG. 2.

FIGS. 5-10 are perspective views of antennas according to other embodiments of the invention.

FIG. 11 is a side view of a transfer mechanism and a substrate of the apparatus of FIG. 2.

FIG. 12 is a perspective cut away view of an apparatus according to another embodiment of the invention.

FIG. 13 is a top view of the grid of the apparatus of FIG. 12.

FIG. 14 is a side view of an apparatus according to another embodiment of the invention.

### DETAILED DESCRIPTION

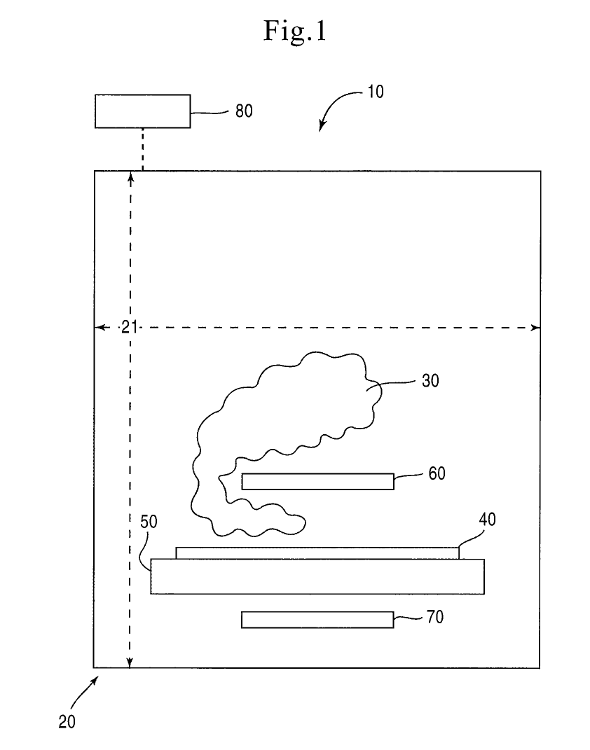

FIG. 1 is a schematic illustration of an etching apparatus 10 according to an embodiment of the invention. The apparatus 10 includes a chamber 20, a transfer mechanism 50, an antenna 60, an optional temperature control mechanism (for heating and/or cooling) 70, and a control mechanism 80, and is usable to apply etching substance 30 to a substrate 40.

The chamber 20 defines an enclosed or a substantially enclosed area or region, referred to as and shown on this embodiment as an interior region 21. The chamber 20 includes several walls that define the interior region 21. The chamber 20 may include any configuration of walls disposed so that such walls define an enclosed or a substantially enclosed volume or region. The walls of the chamber may be comprised of any type of material, so long as the material is configured to contain a variety of species at substantially controlled temperatures and pressures. For example, in one embodiment, the walls of the chamber are made of a metallic substance such as aluminum, iron, nickel, or stainless steel. In yet another embodiment, the walls of the chamber are made of glass.

In the illustrated embodiment, the chamber 20 is configured to contain the etching substance 30, the substrate 40, the transfer mechanism 50, the antenna 60, and the temperature control mechanism 70. In other embodiments, the chamber may contain only a portion of the substrate, or only a portion of the transfer mechanism, or only a portion of the antenna, or only a portion of the temperature control mechanism, or a combination of all or any portions of such components.

The etching substance 30 is disposed within the interior region 21 of the chamber. In one embodiment, the apparatus 10 includes a flow system by which the etching substance 30 can be introduced to the chamber 20 or evacuated from the chamber 20 (the flow system is not shown in schematic). Such a flow system can include any known method for transport of fluid (liquid or gas) substances. For example, in one embodiment the flow system includes a network of pipes and valves and a showerhead. In another embodiment, the flow system includes a pump and a plurality of valves.

The etching substance 30 is formulated to etch a portion of the substrate 40, such as a portion of a surface thereof. The etching substance 30 may be any type of material or chemical that can etch a portion of the substrate 40. It should be understood that the etching substance 30 should be selected based on the type of material or substrate to be etched. For example, in one embodiment, for etching silicon the etching substance 30 is Freon 14 or a mixture of Freon 14 and oxygen. In another embodiment, for etching photoresist the etching substance 30 is oxygen.

The etching substance 30 can include various species, such as a gas, a plasma, or a mixture of gas or plasma. For example, in one embodiment, the etching substance 30 is a gas that is formulated to be activated or transformed into a plasma when the etching substance is placed within an electrical field or exposed to an electrical potential. Accordingly, when the etching substance 30 of such an embodiment is in its plasma state it has a positive charge. In other embodiments, the etching substance is a gas that can be activated or transformed into a plasma by direct current or by microwave radiation.

In another embodiment, the etching substance 30 is a mixture of gas and activated, positively charged plasma. In another embodiment, the etching substance 30 includes a mixture of gases configured to etch a substrate. In other embodiments, other substances known for etching a substrate are used.

The antenna 60 is disposed in the chamber 20 within operative proximity to the etching substance 30 and the substrate 40. The antenna 60 can be supported within the chamber 20 by any known mechanical means. For example, in one embodiment, the antenna 60 is anchored to the walls of the chamber 20. In another embodiment, the antenna 60 can be held in place by sheets of plate glass or using a feed line. In one embodiment, the antenna is electrically isolated from the walls by glass insulation.

The antenna 60 is configured to activate the etching substance 30 such that the etching substance 30 is in a form to etch the substrate 40. The antenna is in coupled to a source of electric potential. For example, in one embodiment the antenna is a radio frequency (RF) antenna that is coupled to an RF transmitter that is disposed outside the chamber. In such an embodiment, the antenna 60 is configured to receive the RF energy transmitted by the transmitter. The transmitter can be tuned to match the antenna with the transmitter using tuning techniques understood by those who are skilled in the art.

In one embodiment, the antenna includes a surface area that is larger than the surface area of the substrate being etched. In one embodiment, the transfer mechanism and/or the substrate, both of which are described in detail below, is electrically grounded, such that an electrical field is present between the antenna and the transfer mechanism and/or the substrate.

The antenna may be formed of any suitable material that can activate the etching substance 30. In one embodiment, the antenna is formed of multiple materials. For example, in one embodiment, the antenna includes glass, ceramic, aluminum, steel, and stainless steel. In another embodiment, the antenna includes a single conductive material such as a metal.

As illustrated in the embodiment of FIG. 1, the substrate 40 is disposed within the interior region 21 of the chamber 20. The substrate 40 is disposed on and supported by the transfer mechanism 50. In another embodiment, a substrate is coupled to the transfer mechanism.

The substrate may be formed of any type of material or chemical that is etchable by some etching substance 30. In one embodiment, the substrate 40 is a semiconductor. For example, in such an embodiment, the substrate includes a material known in the art for use as a semiconductor, a polyimide film, a silicon or silicon oxide material, a polyurethane material, a metallic oxide or a metallic alloy. In one embodiment, the substrate can also include more than one material. For example, in one embodiment, the substrate is made of a plastic or a metal and is coated with any combination of materials such as metal, semiconductor material, dielectric material, and resist. In yet another embodiment, the substrate is comprised of a layer of metal oxide, a layer of dielectric material, and a layer of resistive material. A large number of different layers in any combination with different functions can be repeatedly stacked, patterned and etched in any combination to yield the desired properties, devices or circuits.

The surface of the substrate 40 is etchable by an activated form of the etching substance 30. An embodiment of a substrate formed from multiple layers of material can be configured such that the etching substance 30 etches particular layers of the substrate. For example, in one embodiment, a substrate may be formed of three layers of material. One of the layers of such substrate may be configured to be etched by an activated form of the etching substance 30. In another embodiment, a substrate is formed of six layers of material. Two layers of such substrate may be configured to be etched by an activated form of the etching substance.

The substrate 40 is disposed on the transfer mechanism 50. The embodiment of FIG. 1 shows the transfer mechanism 50 completely disposed within the chamber 20. The transfer mechanism 50 can be any mechanism that is configured to transport the substrate 40 through at least a portion of the chamber 20. For example, in one embodiment, the transfer mechanism is a conveyor system. In another embodiment, the transfer mechanism is a roll to roll system. In other embodiments, only portions of the transfer mechanism are disposed within the chamber.

The transfer mechanism 50 is configured to move the substrate 40 within a process zone. The term “process zone” is used herein to mean the portion of the interior region 21 of the chamber 20 where the etching substance 30 interacts with the substrate 40 to etch the substrate 40. The substrate 40 includes a first portion and a second portion. The transfer mechanism 50 is configured to move the substrate from a first position to a second position. When the substrate 40 is in the first position, the first portion of the substrate 40 is disposed within the process zone and the second portion of the substrate 40 is disposed outside of the process zone. When the substrate 40 is in the second position, the first portion of the substrate 40 is disposed outside of the process zone and the second portion of the substrate is disposed within the process zone.

A temperature control mechanism 70 may be disposed within the chamber 20. In one embodiment, the temperature control mechanism 70 is disposed within the chamber 20 such that the substrate 40 is disposed between the temperature control mechanism 70 and the antenna 60. The temperature control mechanism 70 is configured to control the temperature of the interior region of the chamber 20 and its contents, including the etching substance 30 and the substrate 40. In one embodiment, the temperature control mechanism 70 is configured to maintain the temperature within the chamber 20 between 25° C. and 300° C.

In one embodiment, the temperature control mechanism 70 is anchored to a wall of the chamber 20 via any known fastening means. It may be any type of temperature control mechanism. For example, in one embodiment it is a planar warming plate. In some embodiments, it may be a a cooling mechanism that can remove heat from the substrate and maintain a substrate temperature at, for example, 45° C. when the substrate is too hot rather than too cold. The temperature control mechanism can include both heating and cooling capabilities, and may be implemented as a separate heater and cooling mechanism to ensure temperature control over a wide range of substrate temperatures. For example, cooled copper lines can be installed in addition to a heater, and in another location such as inside the transfer mechanism, to remove heat that is generated during an etching process to maintain a substrate temperature. In one embodiment, a cooling coil can be mounted to the transfer mechanism using, for example, solder to form a planar cooling plate.

The control mechanism 80 is disposed outside of the chamber 20. In other embodiments, portions of the control mechanism can be disposed within the chamber 20. The control mechanism 80 is configured to control the environment of the interior region 21 of the chamber 20 and/or control the items disposed within the interior region 21 of the chamber 20. In one embodiment, for example, the control mechanism regulates the power supplied to portions of the apparatus, the temperature and pressure inside the chamber, the transmitter that interacts with the antenna, and the flow of the etching substance into and out of the chamber. In another embodiment, the control mechanism regulates the temperature and pressure inside the chamber, the drive mechanism for the transfer system, the control valve and flow controller for the source of etching substance, and the power supplied to the antenna. In other embodiments, the control mechanism may perform any of the above mentioned functions, or a combination of such functions.

In another embodiment, the device includes more than one control mechanism. In such an embodiment, the control mechanisms each control one or more of the above-referenced functions. For example, in one embodiment, the device 10 includes power supplies for the antenna, temperature controls, drive controls for the transfer mechanism, a pumping stack and pressure controls for maintaining the pressure within the chamber 20, and gas sources with control valves and flow controls for controlling the flow of the etching substance 30 into and out of the chamber 20.

For example, in one embodiment, the control mechanism and/or the components of the apparatus 10 is configured to maintain the pressure within the chamber 20 between 10 mTorr and 1 Torr.

In use, the apparatus 10 of FIG. 1 is configured to etch a substrate or surface of a substrate. Specifically, the transfer mechanism 50 directs the substrate 40 through the process zone of the apparatus 10 or the portion of the interior region 21 of the chamber 20 where the substrate 40 may be etched. An electrical potential is placed on the antenna 60 such that the antenna 60 activates the etching substance 30 that is disposed within the chamber 20. The activated form of the etching substance 30 then etches the substrate 40 as the transfer mechanism 50 moves the substrate through the process zone.

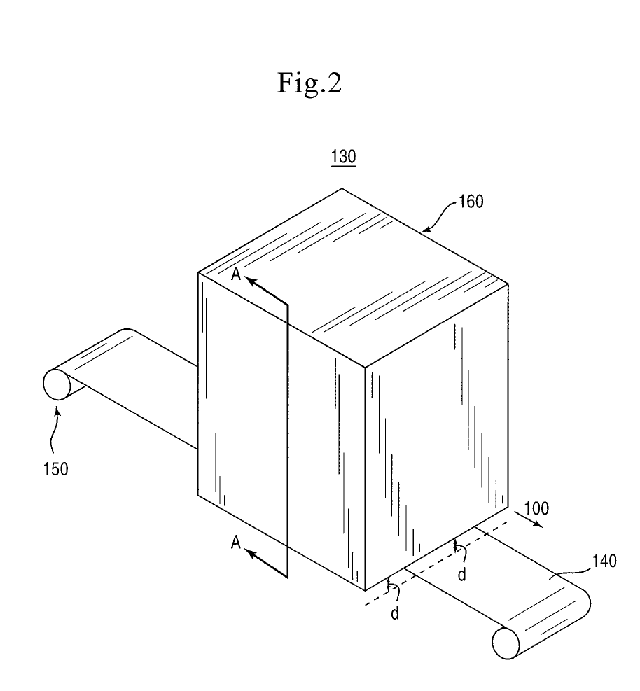

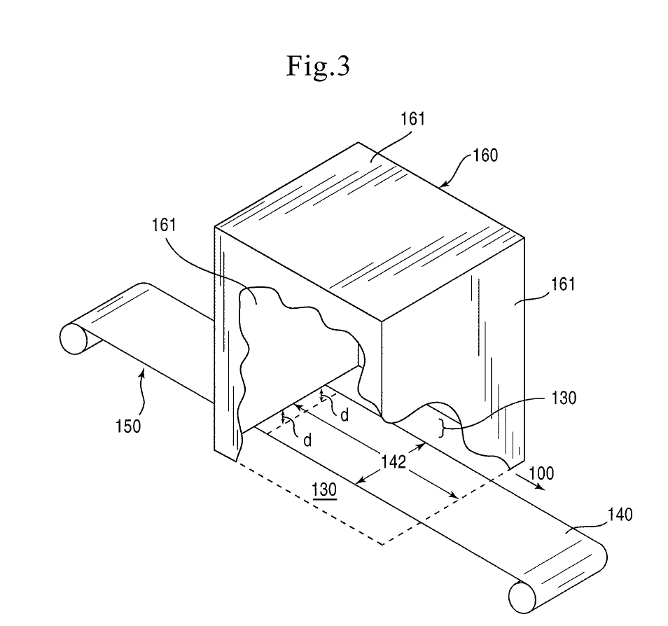

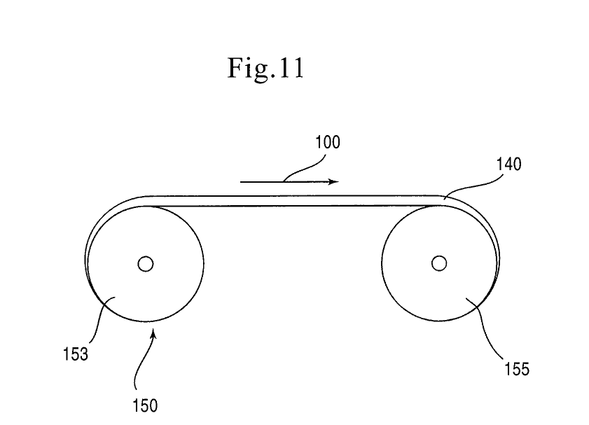

FIGS. 2-4 and 11 illustrate an apparatus according to an embodiment of the invention. FIGS. 2 and 3 illustrate an interior region of a chamber (not illustrated). The chamber is a vacuum chamber and defines an enclosed area. In FIGS. 2-4 and 11, like or similar elements are designated with identical reference numerals, throughout the several views.

The chamber contains an etching substance 130, such as described above, and activated when the etching substance 130 is exposed to an electrical potential such as RF energy. The activated etching substance 130 is a positively charged plasma and is can etch a portion of the substrate 140.

The material of the etching substance 130 is selected depending on the type of material that is to be etched from the substrate 140. For example, to etch a silicon portion of a substrate, a mixture of Freon 14 and oxygen may be used as the etching substance 130. In one embodiment, the ratio of Freon 14 to oxygen is about 10 to 1.

An antenna 160 is disposed within the chamber and in operative proximity to the etching substance 130 and the substrate 140. The antenna 160 is coupled to and supported by the walls of the chamber using known fastening means, for example, threaded fasteners, braces, brackets, or other similar fastening methods using various types of material such as glass sheets.

In the illustrated embodiment, the antenna 160 forms a five-sided, open box. The opening faces the substrate Specifically, the antenna 160 has five side walls including a first wall that is oriented generally parallel to the substrate 140 and adjacent to a second wall, a third wall, a fourth wall, and a fifth wall. The second wall is oriented generally orthogonal to the substrate 140 and adjacent to the first third and fourth walls. The third wall is oriented generally orthogonal to the substrate 140 and adjacent to the first, second, and fifth walls. The fourth wall is oriented generally orthogonal to the substrate 140 and adjacent to the fist second and fifth walls. The fifth wall is oriented generally orthogonal to the substrate 140 and adjacent to the first, third and fourth walls.

The five walls 161 of the antenna 160 and a portion 142 of the substrate 140 collectively define a substantially enclosed volume. An inner surface area of the antenna 160 (the sum of the inner surfaces of the five walls 161) is selected to be greater than the surface area of the substrate 140 that is exposed to the substantially enclosed area. As will be discussed in detail below, this allows the substrate 140 to have a larger negative charge per area. Accordingly, the activated etching substance (in the illustrated embodiment, a positively charged plasma) is attracted to the substrate 140 rather than being attracted to the antenna 160. In the illustrated embodiment, each of the five walls are a few square feet. In other embodiments, the walls of the antenna are of different sizes.

In the illustrated embodiment, the substantially enclosed area defined collectively by the antenna 160 and the substrate 140 is the process zone. In other words, the substantially enclosed area is where the substrate is etched. Accordingly, at least some of the etching substance 130 is disposed within the process zone.

As best illustrated in FIGS. 2 and 3, a portion (the end portions of several of the walls 161 of the antenna 160) of the antenna 160 is disposed distance d from the surface of the substrate 140. In the illustrated embodiment, the distance d is about 0.125 inches (0.32 cm) above the surface of the substrate 140. In other embodiments, the distance d is between 0.125 inches (0.32 cm) and 0.5 inches (1.27 cm). In further embodiments, the distance d is more than 0.5 inches (1.27 cm). The distance d can be varied to avoid problems such as arcing between the antenna 160 and the substrate 140. Also, in some embodiments, the gap formed by the distance between the antenna 160 and the substrate 140 can be blocked using glass.

The antenna 160 is in communication with a transmitter of a control mechanism (not illustrated). The transmitter supplies a voltage potential to the antenna 160. In the illustrated embodiment, the transmitter is an RF transmitter. Accordingly, when the transmitter transmits an RF signal to the antenna, RF energy is applied to the antenna 160. In the illustrated embodiment, the RF energy applied to the antenna 160 is between 10 and 500 watts. In the illustrated embodiment, the transfer mechanism 150 and the substrate 140 (both of which are described in detail below) are electrically grounded.

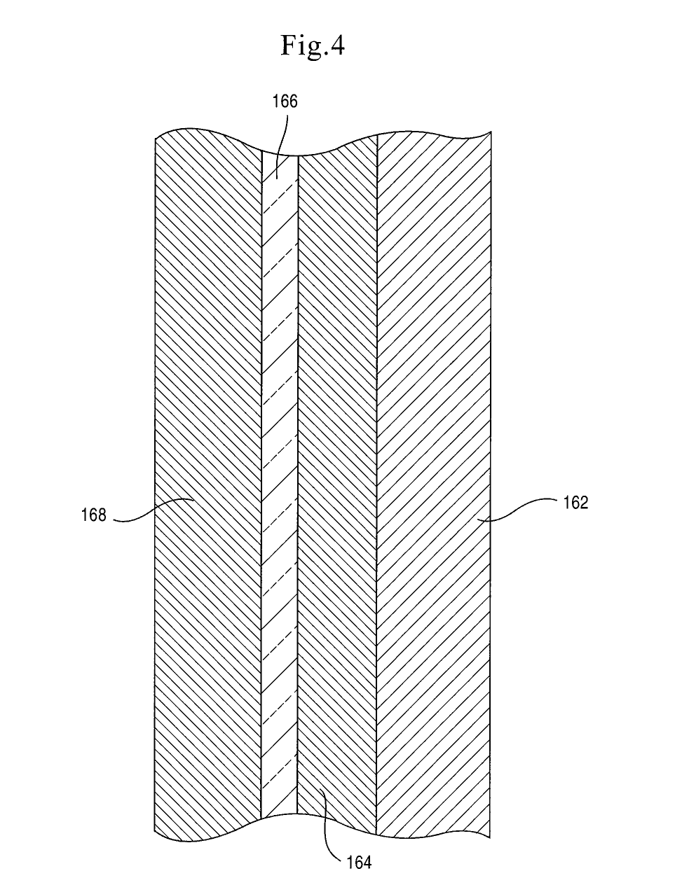

As illustrated in FIG. 4, the antenna 160 is formed of several layers of material. FIG. 4 shows a cross-section of the antenna 160 taken along line A-A of FIG. 2. The antenna 160 includes an outer layer 162, a middle layer 164, an insulating layer 166, and an inner layer 168. In one embodiment, the layers of the antenna 160 may have slots, holes, and/or a channel so that the etching substance 130 may be directed or otherwise forced into the substantially enclosed area defined by the antenna 160 and the substrate 140. In another embodiment, a separate venting system that includes ducts, channels, slots, holes, etc. can be used to remove spent gas from the system.

The outer layer 162 of the antenna 160 includes an aluminum material and is disposed adjacent to the middle layer 164. The outer layer 162 and middle layer 164 can be coupled together to form one piece. In the illustrated embodiment, the outer layer 162 of the antenna 160 has a thickness of about 0.10 inches (0.25 cm). The middle layer 164 of the antenna includes an aluminum material. The middle layer 164 is disposed between the insulating layer 166 and the outer layer 162.

The insulating layer 166 includes a glass material. In one embodiment, the insulating layer 166 includes two layers of glass separated by polyimide tape. The insulating layer 166 is disposed between the middle layer 164 and the inner layer 168. The several layers may be coupled together by any known fastening means, such as, for example, screws or other threaded fasteners.

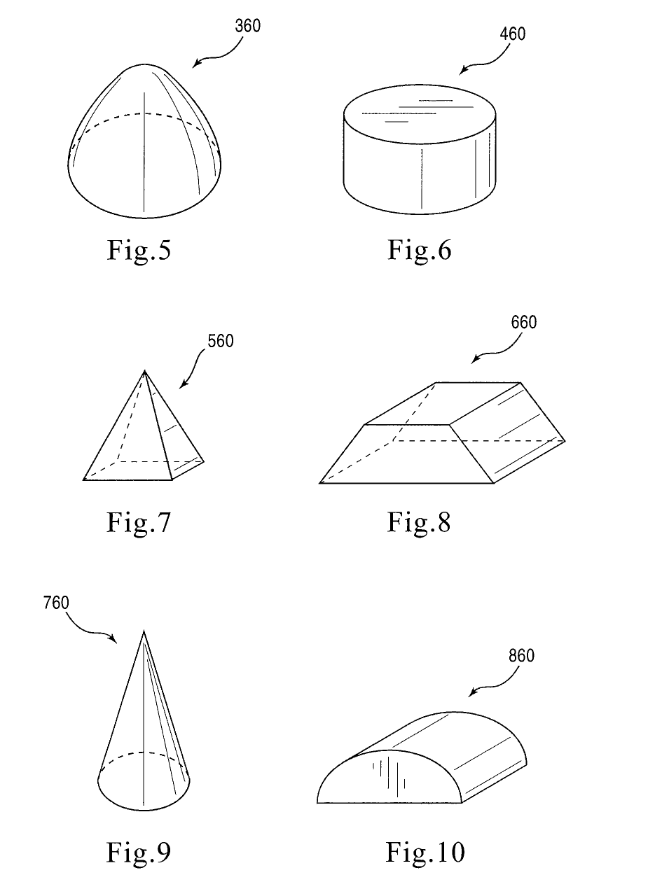

Other embodiments of the antenna are shown in FIGS. 5-10. The antenna can have any configuration, so long as the inner surface of the antenna is larger than the surface area of the portion of the substrate disposed within or exposed to the process zone. For example, in the embodiment shown in FIG. 5 the antenna 360 has a dome-like or hemispherical shape. In the embodiment shown in FIG. 6, the antenna 460 has a cylindrical shape. In the embodiment shown in FIG. 7, the antenna 560 has a pyramid shape. In the embodiment shown in FIG. 8, the antenna 660 has a trapezoid shape. In the embodiment of FIG. 9, the antenna 760 has a conical shape. In the embodiment of FIG. 10, the antenna 860 has a semicircular shape. The embodiments shown in FIGS. 5-10 may be formed of a single layer of material, or of multiple layers of material.

In the illustrated embodiment, the substrate 140 is disposed within the interior region of the chamber. In the illustrated embodiment, the substrate 140 is about 13 inches (33.02 cm) wide. In other embodiments, the substrate is between 13 inches (33.02 cm) and 36 (91.44 cm) inches wide. In further embodiments, the substrate is larger than 36 inches (91.44 cm) wide. In yet further embodiments, the substrate is smaller than 13 inches (33.02 cm) wide. In one embodiment, a length of about 10 inches (25.4 cm) is configured to be disposed within the interior region of the chamber at any one time. The overall length of the substrate in one embodiment is about 10,000 inches (25,400 cm). The surface area of the antenna and/or the substrate can be scaled up or down by several orders of magnitude beyond the dimensions mentioned herein.

The substrate 140 includes a base layer and a layer of material that can be etched by the activated etching substance 130. In the illustrated embodiment, the substrate 140 includes a plastic base layer and a silicon layer that can be etched by the activated etching substance 130. In one embodiment, the substrate 140 is patterned using a known lithography process prior to etching.

As best illustrated in FIGS. 3, 4, and 11, in the illustrated embodiment, the substrate 140 is disposed on and supported by a transfer mechanism 150. The transfer mechanism 150 is configured to convey or move the substrate 140 through the process zone of the chamber. Specifically, the transfer mechanism conveys a first portion of the substrate through the process zone while a second portion of the substrate is disposed outside of the process zone. Subsequently, the transfer mechanism 150 transfers the second portion of the substrate 140 through the process zone while the first portion is disposed outside of the process zone.

The transfer mechanism 150 includes a source roll 153 and a take-up roll 155. A first end portion of the substrate 140 is coupled to the source roll 153 and a second end portion of the substrate 140 is coupled to the take-up roll 155. The substrate 140 may be wound onto the source roll 153. The source roll 153 and the take-up roll 155 are each arranged to rotate to transfer the substrate 140 from the source roll 153 to the take-up roll 155. Specifically, the source roll 153 and the take-up roll 155 may each rotate clockwise to move the substrate 140 in the direction of arrow 100 and thereby transfer the substrate 140 from the source roll 153 to the take-up roll 155. In the illustrated embodiment, the transfer mechanism moves the substrate 140 through the process zone at a rate of 5 inches (12.78 cm) per minute. In another embodiment, the transfer mechanism moves the substrate through the process zone at a rate faster than 5 inches (12.7 cm) per minute. In yet another embodiment, the transfer mechanism moves the substrate through the process zone at a rate slower than 5 inches (12.7 cm) per minute.

In the illustrated embodiment, the source roll 153 and the take-up roll 155 are supported within the chamber by a set of bearings and a bearing plate that is bolted within the etching chamber. In other embodiments, the transfer mechanism is supported within the chamber via other known mechanisms.

The apparatus of FIGS. 2-4 and 11 includes a temperature control mechanism disposed within the chamber (not illustrated) and configured to control the temperature of the interior region of the chamber and its contents. In one embodiment, the temperature control mechanism is disposed such that the portion of the substrate 140 that is disposed within the process zone is disposed between the antenna 160 and the temperature control mechanism. In one embodiment the temperature control mechanism is a thermal electric heater. In another embodiment, it is a metal plate containing resistive cartridge heaters.

The apparatus illustrated in FIGS. 2-4 and 11 includes a control mechanism (not illustrated). The control mechanism is disposed outside of the chamber and is configured to control the various devices of the apparatus. For example, the control mechanism is configured to control the transfer mechanism 150, the power supplied to the antenna 160, the pressure of the etching substance within the chamber, and the heater to control the temperature within the chamber. In other embodiments, several control mechanisms may function together to control the various devices of the apparatus.

In one embodiment, the control mechanism and/or the components of the apparatus are configured to maintain a pressure within the chamber of about 200 mTorr. The pressure of the chamber is chosen so that the mean free path of the plasma ions will be long enough that the plasma ions will not collide with gas particles, lose energy, and fail to effectively etch the substrate.

In use, the apparatus of FIGS. 2-4 and 11 is configured to etch a substrate or surface of a substrate. An electrical potential is placed on the antenna 160 (via an RF transmitter) such that the etching substance 130 disposed within at least the process zone is activated (causing the etching substance to become a plasma). As electrons that were once associated with the unactivated etching substance accumulate on the inner surface of the antenna 160 and the surface of the substrate 140 that is exposed to the process zone, the antenna 160 and the substrate 140 will become negatively charged. As the surface area of the substrate 140 is smaller than the surface area of the antenna 160, the substrate 140 will have a larger negative charge per area than the antenna 160. Accordingly, the activated etching substance 130 (positively charged plasma) will be attracted to the surface of the substrate 140. The activated etching substance 130 that contacts the surface of the substrate etches the surface of the substrate 140.

Once the portion of the substrate that is disposed within the process zone has been etched, the transfer mechanism 150 moves or transfers the etched portion of the substrate outside the process zone (onto the take-up roll 155) and moves an unetched or unprocessed portion of the substrate 140 into the process zone (from the source roll 153).

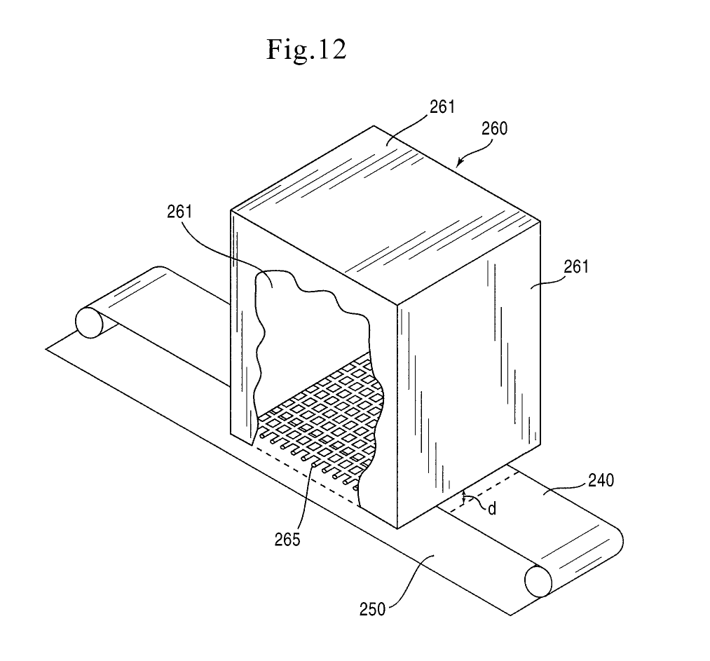

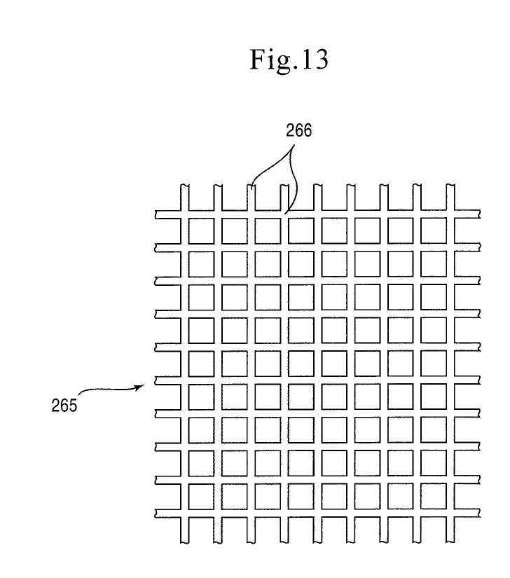

FIGS. 12 and 13 illustrate a portion of an apparatus according to another embodiment of the invention. As illustrated in FIG. 12, the apparatus includes a substrate 240, a transfer mechanism 250, an antenna 260, and an etching substance disposed within a chamber (not illustrated). The apparatus also includes a grid 265 disposed within the area collectively defined by the antenna 260 and a portion of the surface of the substrate 240. In other words, the grid 265 is disposed within the process zone. The grid 265 causes the ions in the plasma to directional etch the substrate 240 resulting in an anisotropic etch of the substrate 240.

The grid 265 may be supported within process zone by any known mechanism. For example, the grid 265 may be fastened to the inner walls of the antenna using screw or threaded fasteners. In one embodiment, the grid is removably coupled to an inner wall of the antenna. In another embodiment, the grid is supported on an insulated frame or stand. In yet another embodiment, the grid can be mounted using standoffs such as ceramic standoffs that are protected by Teflon washers.

In the illustrated embodiment, the grid 265 is oriented such that it is disposed in a plane that is parallel to the plane defined by the portion of the substrate 240 that is disposed within the process zone. Specifically, the grid 265 is disposed 0.25 inches (0.64 cm) away from the portion of the substrate 240 that is disposed within the process zone. In other embodiments, the grid is disposed further from the portion of the substrate that is disposed within the process zone. In further embodiments, the grid is disposed closer to the portion of the substrate that is disposed within the process zone.

The grid 265 is sized such that it extends above the entire width of the substrate 240. In the illustrated embodiment, the grid 265 is about 14 inches (35.56 cm) by about 10 inches (25.4 cm). The grid 265 is mounted about 1 inch from any conductive surface to prevent problems such as arcing. In other embodiments, the grid has a different size and can be mounted at different distances from any surface. The grid can also include a mechanism, such as a spring loaded tensioning bar, to take up any change in grid wire length caused by thermal expansion.

As illustrated in FIG. 13, the grid 265 includes several wires 266 that form a mesh having regular openings. In one embodiment, the mesh is made of 0.02 inch (0.05 cm) diameter stainless steel wires that are spaced about 0.188 inches (0.48 cm) apart. The thickness of the wire used in the grid can be varied to meet the needs of a particular process and application.

Although the grid is illustrated as including several wires 266 having regularly spaced square openings, the grid 265 can include wires spaced in a variety of configurations. For example, the wires may define openings that are rectangular. Additionally, the grid 265 may include wires that define irregularly spaced openings. In other embodiments, the grid 265 can be formed using a solid sheet of a conductor with holes punched into it in any shape, arrangement, and size. For example, a grid can be solid sheet of a conductor with triangular holes. The conductor can include materials such as Tungsten, Tantalum, or Molybdenum or another material of sufficient heat resistance and conductivity. In other embodiments, a set of parallel wires can be used instead of a grid.

The grid 265 is configured to have a negative bias placed on it. In the illustrated embodiment, the grid 265 is configured to have a negative bias of about 250 volts applied to it. In other embodiments, the grid is configured to have a negative bias of up to 500 volts applied to it.

Accordingly, in use, the grid 265 is configured to attract the activated etching substance (positively charged plasma). As the grid 265 is disposed close to the substrate 240, the activated etching substance 230 is attracted to the grid 265, passes through the openings defined by the grid 265, and contacts the surface of the substrate 240. Accordingly, the activated etching substance 230 etches the surface of the substrate 240.

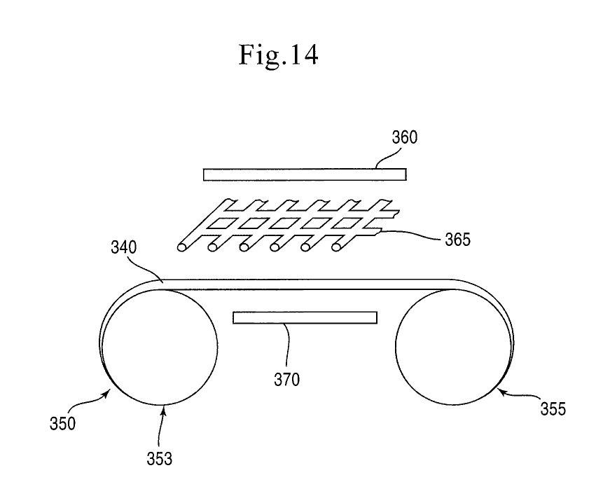

FIG. 14 is a side view of a portion of an apparatus according to another embodiment of the invention. The apparatus includes a transfer mechanism 350, an antenna 360, a heater 370, and a grid 365 disposed within a chamber (not illustrated) to etch a substrate 340 with an etching substance (not illustrated).

The antenna 360 is planar and is disposed within a plane that is parallel to both the plane defined by the grid 365 and the plane defined by the portion of the substrate 340 disposed within the process zone. In one embodiment, the grid 365 is disposed between 0.125 inches (0.32 cm) and 0.25 inches (0.64 cm) away from the substrate 340 and the antenna 360 is disposed between 0.125 inches (0.32 cm) and 1 inch (2.54 cm) away from the grid 365. The distance of the grid 360 from the substrate 340 can be increased beyond 1 inch in some embodiments.

Similar to the above-described embodiments, an electrical potential is placed on the antenna 360 such that the etching substance disposed within the chamber is activated (causing the etching substance to become a positively charged plasma). Additionally, a negative potential is placed on the grid 365. Accordingly, the activated etching substance (positively charged plasma) is attracted to the grid 365. The activated etching substance passes through the openings defined by the grid 365 and contacts the surface of the substrate 340.

It should be understood that it is not necessary, in this embodiment of the apparatus, that the antenna 360 be larger than the portion of the substrate 340 that is being etched.

As illustrated in FIG. 14, the temperature control mechanism 370 is disposed within the chamber such that the substrate 340 is disposed between the antenna 360 and the temperature control mechanism 370.

Although the present invention has been described in considerable detail with reference to specific embodiments thereof, it will be apparent to one skilled in the art that various changes and modifications can be made therein without departing from the spirit and scope thereof. For example, in one embodiment, the antenna may be configured to move over a stationary substrate such that the process zone moves within the chamber to etch various portions of the substrate. Thus, it is intended that the present invention covers the modifications and variations of this invention provided they come within the scope of the appended claims and their equivalents.

What is claimed is:

1. An apparatus for etching a substrate having a first portion and a second portion, comprising:
a chamber having a process zone, the chamber being configured to contain a substrate, an etching substance, and an antenna;
the antenna being configured to activate the etching substance;
the etching substance being formulated to etch the substrate when the etching substance is activated; and
a transfer mechanism, the transfer mechanism being configured to move the substrate from a first position to a second position, the first portion of the substrate being disposed within the process zone and the second portion of the substrate being disposed outside the process zone when the substrate is in its first position, the first portion of the substrate being disposed outside the process zone and the second portion disposed within the process zone when the substrate is in its second position.

2. The apparatus of claim 1, further comprising a control mechanism configured to control the pressure within the chamber.

3. The apparatus of claim 1, wherein the etching substance includes a plasma, a gas, or a mixture of plasma and gas.

4. The apparatus of claim 1, wherein the etching substance includes at lease one of a direct current plasma and a microwave plasma.

5. The apparatus of claim 1, wherein the etching substance is formulated to etch one or more of a metallic oxide, a ceramic, a metallic alloy, or a polymeric material.

6. The apparatus of claim 1, wherein the antenna has an interior surface, the interior surface of the antenna being larger than the surface area of at least a portion of the substrate.

7. The apparatus of claim 1, wherein the substrate includes a polyimide webbing.

8. The apparatus of claim 1, wherein the transfer mechanism includes a first member and a second member, the first member being configured to transfer the at least a portion of the substrate to the second member.

9. The apparatus of claim 7, wherein the first member is a feeder roll configured to retain the at least a portion of the substrate prior to the at least a portion of the substrate being moved through the process zone, the second member is a take up roll configured to retain the at least a portion of the substrate after the at least a portion of the substrate is transferred through the process zone.

10. The apparatus of claim 1, further comprising a heating element configured to heat at least one of the substrate and the etching substance.

11. The apparatus of claim 1, wherein the antenna is a radio frequency antenna.

12. The apparatus of claim 1, wherein the antenna has a first portion, a second portion, a third portion, a fourth portion, and a fifth portion, the first portion being oriented generally parallel to the substrate and adjacent to the second, third, fourth, and fifth portions, the second portion being oriented orthogonal to the substrate and adjacent to the first, third, and fourth portions, the third portion being oriented orthogonal to the substrate and adjacent to the first, second, and fifth portions, the fourth portion being oriented orthogonal to the substrate and adjacent to the first, second, and fifth portions, the fifth portion being oriented orthogonal to the substrate and adjacent to the first, fourth, and third portions.

13. The apparatus of claim 1, wherein the antenna and the at least a portion of the substrate collectively define a substantially enclosed area, the antenna having an interior surface area, the interior surface area of the antenna being larger than a surface area of a portion of the substrate adjacent to the interior surface area of the antenna.

14. The apparatus of claim 1, wherein the antenna has a dome-like shape, wherein at least a portion of the interior surface area of the dome-like shape and the at least a portion of the substrate collectively define a substantially enclosed area.

15. The apparatus of claim 1, further comprising a grid disposed between the antenna and the substrate, the grid being configured to attract the activated etching substance and cause anisotropic etching.

16. A processing method for etching a substrate including at least a first etchable material in a desired configuration using an etching substance formulated, when activated, to etch the etchable material and contained within a chamber and comprising the steps of:
placing the substrate on a transfer system configured to transfer at least a portion of the substrate through a process zone, the process zone being located in the chamber;
transferring the substrate from a first position to a second position, the first position having a first portion of the substrate disposed inside the process zone and a second portion of the substrate disposed outside the process zone, the second position having the first portion of the substrate disposed outside the process zone and the second portion disposed inside the process zone; and
applying an radio frequency energy or a voltage potential to an antenna to activate the etching substance.

17. An apparatus for etching a substrate including an etchable material using an etching substance formulated to etch the etchable material when activated, comprising:
a chamber configured to contain an etching substance and the substrate;
an antenna, disposed within the chamber, the antenna configured to activate the etching substance; and
a grid, disposed within the chamber between the antenna and the substrate, the grid being configured to attract the etching substance.

18. The apparatus of claim 17, further comprising:
a transfer mechanism, the transfer mechanism being configured to move the substrate from a first position to a second position, the first position having the first portion disposed outside the process zone and the second portion disposed within the process zone, the second position having the first portion disposed within the process zone and the second portion disposed outside the process zone.

19. The apparatus of claim 17, wherein the grid is disposed between about 0.125 inches to 1 inch away from a surface of the substrate.

20. The apparatus of claim 17, wherein the grid includes a plurality of wires.

21. The apparatus of claim 20, wherein the plurality wires include steel.

22. The apparatus of claim 17, wherein the grid is configured to accumulate a voltage potential from about 0 to −500 volts.

23. The apparatus of claim 17, wherein the grid is removable from the chamber.

24. The apparatus of claim 17, wherein the grid is configured to cause anisotropic etching of the substrate.

25. An apparatus for etching a substrate including material that can be etched by an etching substance, comprising:
a chamber configured to contain the etching substance and the substrate;
an antenna disposed within the chamber, the antenna being configured to collectively, with at least a portion of the substrate, define a substantially enclosed area, the antenna has an interior surface, the interior surface of the antenna being larger than the surface area of the at least a portion of the substrate.

26. The apparatus of claim 25, further comprising:
a transfer mechanism, the transfer mechanism being configured to move the substrate from a first position to a second position, the first position having a first portion of the substrate disposed within the process zone and a second portion of the substrate disposed outside the process zone, the second position having the first portion of the substrate disposed outside the process zone and the second portion of the substrate disposed within the process zone.

27. The apparatus of claim 25, wherein the antenna has a first portion, a second portion, a third portion, a fourth portion, and a fifth portion, the first portion being oriented generally parallel to the substrate and adjacent to the second, third, fourth, and fifth portions, the second portion being oriented orthogonal to the substrate and adjacent to the first, third, and fourth portions, the third portion being oriented orthogonal to the substrate and adjacent to the first, second, and fifth portions, the fourth portion being oriented orthogonal to the substrate and adjacent to the first, second, and fifth portions, the fifth portion being oriented orthogonal to the substrate and adjacent to the first, fourth, and third portions.

28. The apparatus of claim 25, the antenna being configured to activate the etching substance.

29. The apparatus of claim 25, further comprising: a grid disposed between the antenna and the substrate, the grid being configured to move the activated etching substance to the substrate.

30. The apparatus of claim 25, wherein the antenna includes a plurality of layers.

31. The apparatus of claim 25, wherein the antenna is disposed between about 0.25 inches and 0.125 inches away from the substrate.

32. The apparatus of claim 25, wherein the substrate is grounded.
